(19) United States
(12) Patent Application Publication
(10) Pub. No.: US 2020/0118786 A1
(43) Pub. Date: Apr. 16, 2020

(54) SYSTEM AND METHOD FOR SELECTIVE AUTOFOCUS

(71) Applicant: Applied Materials, Inc., Santa Clara, CA (US)

(72) Inventors: Bernhard G. MUELLER, Finsing (DE); Kulpreet Singh VIRDI, München (DE); Nikolai KNAUB, München (DE)

(21) Appl. No.: 16/161,031

(22) Filed: Oct. 15, 2018

(51) Int. Cl. H01J 37/21; H01J 37/22; H01J 37/26

(52) U.S. Cl. CPC H01J 37/21; H01J 37/222; H01J 2237/221; H01J 2237/216; H01J 37/263

(57) ABSTRACT

A system and method for focusing a scanning electron microscope (SEM) comprise acquiring a first SEM image of a sample using a first focus condition, analyzing the first SEM image to determine contrast change measurements, determining a region of interest based on the contrast change measurements, adjusting the SEM from the first focus condition to a second focus condition based at least in part on the region of interest, wherein the first focus condition differs from the second focus condition, and acquiring a second SEM image of the sample using the second focus condition.

### BACKGROUND

### Field

Embodiments of the present disclosure generally relate to apparatus and methods for focusing a scanning electron microscope (SEM), and, more particularly, to a selective focus system and method for a scanning electron microscope.

### Description of the Related Art

In various instances, SEMs are utilized to examine circuit level features of an electronic device. For example, a SEM may be utilized to examine electrodes, transistors, and/or connections of an electronic device. In various instances, an SEM acquires multiple images which are processed to determine the optimum focus conditions for the SEM. Various autofocus methods may be utilized to determine the sharpness (or contrast) gradient of each image and the optimum focus conditions of the SEM. The optimum focus conditions are utilized by the SEM to acquire an image where the circuit level features are sharp and the image will support image processing algorithms for defect review (DR) and/or critical dimension (CD) measurements.

The optimum focus condition may be typically found by variation of focusing influencing parameters of the SEM. For example, an objective lens current of the SEM, acceleration voltage of the SEM, working distance of the SEM, and/or other focus influencing parameters of the SEM may be varied. Typically, during an autofocus operation, one or more of the focus influencing parameters of the SEM is varied as images are acquired. The images are processed to find the image having the highest level of sharpness (or contrast) gradient. Typically, only a portion of each image is processed to increase the speed of the autofocus operation. Further, the focus condition of the SEM is set to the focus condition used to acquire the image having the highest sharpness gradient.

While, the above described autofocus operation is typically able to determine the optimum focus condition for an SEM device, in instances where the electronic device has a limited number of structural features (e.g., circuit features), the autofocus operation may fail as the portion of each image that is analyzed may have a low sharpness gradient. As the sharpness gradient of each of the images may fail to indicate that any of the images may be utilized to focus the SEM, the autofocus operation may fail. Thus, as performing an autofocus operation on an electronic device having a limited number of structural features may fail, the SEM may not be accurately examine the circuit level features of the electronic device.

However, there is a need for an improved autofocus operation that may be utilized for electronic devices having limited number of structural features such that the circuit level features of those electronic devices may be examined.

### SUMMARY

In one embodiment, a method for focusing a scanning electron microscope (SEM) comprises acquiring a first SEM image of a sample using a first focus condition, analyzing the first SEM image to determine contrast change measurements, determining a region of interest based on the contrast change measurements, adjusting the SEM from the first focus condition to a second focus condition based at least in part on the region of interest, wherein the first focus condition differs from the second focus condition, and acquiring a second SEM image of the sample using the second focus condition.

In one embodiment, a computer program product for focusing a scanning electron microscope (SEM) comprises a non-transitory computer-readable storage medium having computer-readable program code embodied therewith. The computer-readable program code is executable by one or more computer processors to acquire a first SEM image of a sample using a first focus condition, analyze first SEM image to determine contrast change measurements, determine a region of interest based on the contrast change measurements, adjust the SEM from the first focus condition to a second focus condition based at least in part on the region of interest, wherein the first focus condition differs from the second focus condition, and acquire a second image of the sample using the second focus condition.

A testing device comprises a scanning electron microscope (SEM), and a processing system coupled to the SEM and configured to acquire a first SEM image of a sample using a first focus condition, analyze the first SEM image to determine contrast change measurements, determine a region of interest based on the contrast change measurements, adjust the SEM from the first focus condition to a second focus condition based at least in part on the region of interest, wherein the first focus condition differs from the second focus condition, and acquire a second image of the sample using the second focus condition.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a block diagram of an imaging device, according to one or more embodiments.

FIG. 2 illustrates an example field of view, according to one or more embodiments.

FIG. 3 illustrates example graphs of contrast gradients, according to one or more embodiments.

FIG. 4 illustrates a method of focusing an imaging device, according to one or more embodiments.

FIG. 5 illustrates an example FOV, according to one or more embodiments.

To facilitate understanding, identical reference numerals have been used, where possible, to designate identical elements that are common to the figures. It is contemplated that elements disclosed in one embodiment may be beneficially utilized in other embodiments without specific recitation thereof with respect thereto.

### DETAILED DESCRIPTION

Embodiments of the present disclosure generally relate to an improved autofocus technique for a scanning electron microscope (SEM). The autofocus technique described herein improves the ability to focus the SEM when a sample has a limited amount of circuit level features (e.g., structural features). For example, the autofocus technique uses a coarse image, which may be slightly out of focus, to determine an area of the image that comprises circuit level features. A region of interest (ROI) may be defined based on the area, and then one or more images of the ROI may be utilized to determine the optimum focus parameters for the SEM.

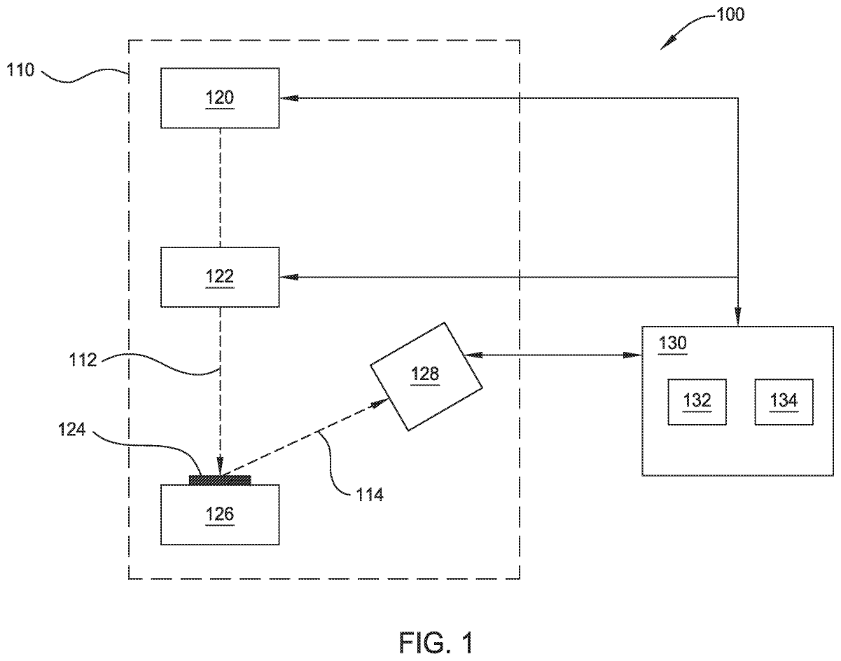

FIG. 1 illustrates an example imaging device 100. The imaging device 100 includes an SEM 110 and processing system 130. In one embodiment, the SEM 110 includes an electron gun 120, a lens assembly 122, stage 126, and a detector assembly 128. The SEM 110 is coupled to processing system 130. In one embodiment, a sample 124 undergoing examination may be positioned on the stage 126. Further, the SEM 110 may be configured to acquire one or more images of the sample 124.

In one embodiment, the electron gun 120 may include, but is not limited to, a field emission gun (cathode). The electron gun 120 may be configured to output a primary electron beam as a predetermined emission current. In one embodiment, an acceleration voltage is applied between a cathode and anode of the electron gun 120 to output a beam 112 toward the lens assembly 122.

The beam 112 may be shaped by the lens assembly 122 before the beam is emitted on to the sample 124. In one embodiment, the lens assembly 122 may be configured to converge the beam and/or eliminate unnecessary regions of the beam before the beam is scanned on to the sample 124.

The lens assembly 122 may be adjustable to control the focus of the beam 112 generated by electron gun 120.

As illustrated in FIG. 1, the SEM 110 may be configured to output a single beam 112. In other embodiments, the SEM 110 may be a multi-beam imaging device. In such embodiment, the electron gun 120 may be output multi-beams. In other embodiments, the lens assembly 122 may be configured to split a beam provided by the electron gun 120 in to multiple beams.

In one or more embodiments, a sample 124 may be any object that is to be examined by the imaging device 100. For example, in one embodiment, the sample 124 may be a substrate having one or more layers including one or more circuit elements. The circuit elements may include traces, electrodes, transistors, connectors, and the like. In one specific embodiment, the sample 124 is a display panel having a glass substrate. The different layers of the glass substrate may have different circuit elements. For example, the various layers may include gate electrodes, source electrodes, transistors, pixel electrodes and/or connectors.

The detector assembly 128 may acquire one or more images of the sample 124 positioned on the stage 126. The detector assembly 128 receives a signal 114 from the sample 124. In one embodiment, beam 112 causes a corresponding signal, e.g., the signal 114). The images acquired by the detector assembly 128 may be output to processing system 130, where the images may be analyzed. In one or more embodiments, the detector assembly 128 is configured to acquire images with various different focus conditions. Further, the detector assembly 128 may be configured to acquire a single image of the sample 124 based on an optimum focus condition.

In one or more embodiments, the detector assembly 128 has a field of view (FOV) that corresponds to the size of the image acquired with the detector assembly 128.

The processing system 130 may control the functionality of the SEM 110. The processing system 130 may include a programmable central processing unit (CPU) 132 that is operable with a memory 134. In various embodiments, the processing system 130 may be referred to as a controller. The processing system 130 may additionally include or be configured to communicate with a mass storage device (not shown), an input control unit, and a display unit (not shown), such as clocks, cache, input/output (I/O) circuits, and the like, coupled to the various components of the SEM 110 to facilitate control of the SEM 110. The processing system 130 further includes support circuits (not shown). In one embodiment, the CPU 132 may be one of any form of general purpose computer processor that can be used in an industrial setting for controlling various chambers and sub-processors. The memory 134 is in the form of computer-readable storage media that contains instructions, that when executed by the CPU 132, facilitates the operation of the SEM 110. The instructions in the memory 134 are in the form of a program product such as a program that implements the method of the present disclosure. In various embodiments, the processing system 130 includes multiple CPUs and various memory elements.

The processing system 130 may be configured to vary one or more focusing influencing parameters of the SEM 110, such that each image acquired by the detector assembly 128 has a different focus. In one embodiment, the processing system 130 is control an object lens current of lens assembly 122, an acceleration voltage of the electron gun 120, a working distance of the SEM 110 (e.g., a distance between lens assembly 122 and stage 126), and/or other focus influencing parameters.

In one or more embodiments, the processing system 130 processes the images and/or data acquired by the detector assembly 128. For example, the processing system 130 may determine a contrast gradient (e.g., sharpness gradient) for each image and determining an image having the highest contrast gradient.

The images acquired by SEM 110 may be utilized to detect one or more defects within the sample 124 and/or make measurements of features within the sample 124. For example, an image may be utilized to study an identified defect to determine a cause of the defect. Further, an image may be utilized to make a measurement of structural features. For example, a measurement of a connector region, and/or a width of an electrode may be made.

In one embodiment, the processing system 130 performs an autofocus function on the SEM 110 to ensure that the images acquired by the SEM 110 and analyzed by the processing system 130 are in-focus and have a high level of sharpness (e.g., contrast between pixels). In some embodiments, imaging device 100 acquires multiple images, each having a different focus. The images are analyzed to determine a sharpness level for each image, or for a portion of the image that is analyzed. The image having the highest amount of sharpness (e.g., highest contrast gradient) may be used to set the focus parameters of the SEM 110. In one embodiment, only a portion of each image is analyzed to determine the contrast gradient for the image to reduce the amount of time required to analyze each image. However, it may be possible that the area of each image selected to be analyzed may lack sufficient structural features. Thus, the processing system 130 may fail to identify an image having a contrast gradient that may be utilized for autofocus.

In various embodiments, the contrast gradient is determined by comparing each pixel to a neighboring pixel, and unless some of the pixels are brighter than the other pixels, the contrast gradient may be calculated as having a low value for the image.

Imaging device 100 may be part of a larger testing system. For example, imaging device 100 may be part of testing system configured to examine identified defects within a display glass substrate. Further, the testing system may be utilized to examine display glass substrates after processing (e.g., electrodes, transistors, and/or connectors are formed within the layers of the display glass substrates) to generate measurements of structural features of the display glass substrate. In one embodiment, the processing system 130 is remote from the SEM 110. For example, the SEM 110 may be mounted to a testing chamber of a testing system and the processing system 130 may be housed external from the testing chamber. Further, the processing system 130 may be also receive input from an input device (e.g., mouse, keyboard, touch screen, etc.) and output data to a display device.

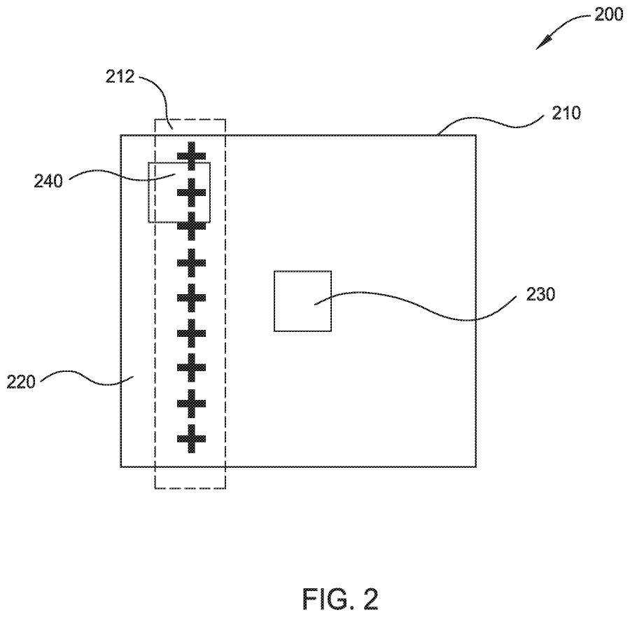

For example, FIG. 2 illustrates image 200 having field of view (FOV) 210. FIG. 2 includes structural features 212. Further, image 200 includes region of interest (ROI) 220, ROI 230 and ROI 240. ROI 220 corresponds to the entirety of FOV 210 and ROI 230 and 240 are at least similar in size but correspond to different area of FOV 210. For example, ROI 230 corresponds to a central region of FOV 210 that is devoid of any structural features and ROI 240 corresponds to a region of FOV 210 that includes structural features (e.g., structural features 212). In one embodiment, ROI 240 is less than the ROI 230.

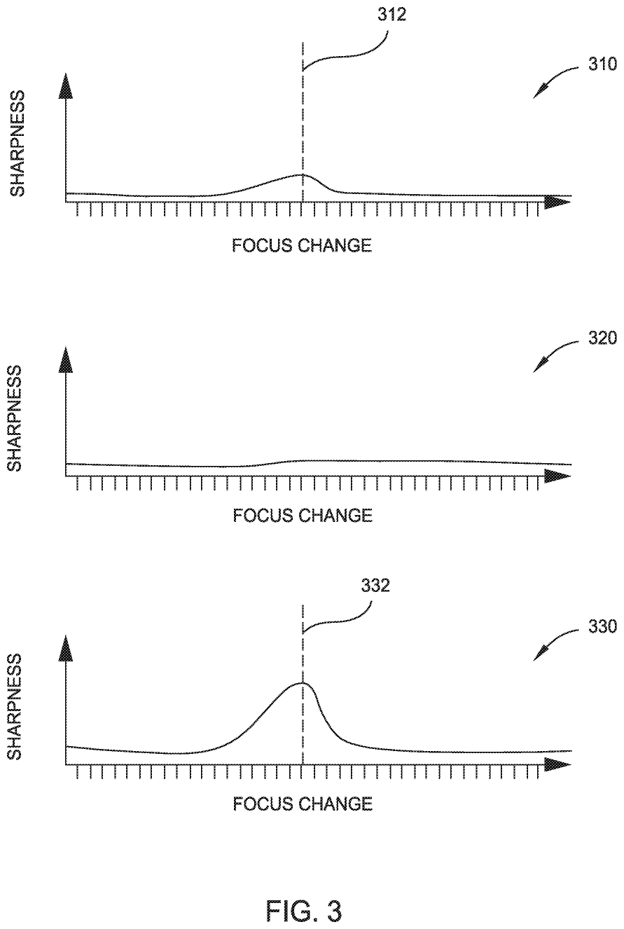

In one embodiment, the contrast gradient for each ROI 220, 230, 240 may differ. For example, by analyzing images of each ROI, it is apparent that the contrast gradient (e.g., sharpness variation or gradient) for the image 200 difference. For example, graphs 310, 320, and 330 of FIG. 3 illustrate graphs of a contrast gradient for images of each RIOs 220, 230, and 240, respectively.

Each of FIG. 3 shows graphs 310, 320, and 330 that illustrate focus change versus sharpness a sharpness value. Each point along the focus change axis to a different image acquired with different focus conditions. For example, the focus conditions of the SEM 110 are changed between acquisitions of each image. Each image is analyzed to determine a sharpness value (e.g., contrast gradient value), which may utilized to generate each corresponding graph. The peak value of sharpness value may be determined, and the image having the peak sharpness value may be used to set the focus of the SEM.

As can be seen, the graphs 310 and 330 include a discernable peak sharpness value (sharpness values 312 and 332, respectively), while graph 320 lacks a discernable peak sharpness value. Accordingly, ROI 220 and 240 each include one or more portions of structural features 212 while ROI lacks structural features 212. However, the peak sharpness value 312 is less than peak sharpness value 332, as the ROI 220 includes a smaller number of structural features relative to the evaluated area of the ROI 220, as compared to that of the ROI 240. Accordingly, the graph 330, which is generated from the ROI 240, has a pronounced sharpness peak sharpness value due to the higher number of structural features relative the evaluated area of the ROI 240.

Further, as the area of ROI 220 is greater in size than both ROI 230 and 240, the amount of time required to analyze ROI 220 is also greater than that of ROI 230 and 240. In one embodiment, the amount of time required to analyze ROI 220 may negatively affect the performance of the imaging device 100, such that analysis of the sample 124 may fail and/or may not be completed within a required time allotment. Further, as ROI 230 lacks structural features, the corresponding graph 320 lacks an image having a peak sharpness value and the autofocus process performed using ROI 230 may fail.

Thus, in an embodiment where the processing system 130 relies upon ROI 220 to determine the optimum focus condition, the optimum focus condition may fail to be identified. Similarly, in an embodiment where the processing system 130 relies upon ROI 240 to determine the optimum focus condition, the optimum focus condition may fail to be identified as the ROI lacks structural features. Contrary, in an embodiment where the processing system 130 relies upon ROI 230 to determine the optimum focus condition of the SEM 110, the optimum focus condition may be determined. However, the imaging device 100 needs to be able to identify ROI 230. For example, in one embodiment, ROI 230 may be determined by first taking a course (e.g., out of focus) image of the sample 124, processing the image to identify changes in contrast and determining an ROI from the course image, where the location of the ROI corresponds to areas of the image that does include structural features (e.g. structural features 212). In one embodiment, after the ROI is determined the ROI may be utilized to determine the optimum focus condition of the SEM 110.

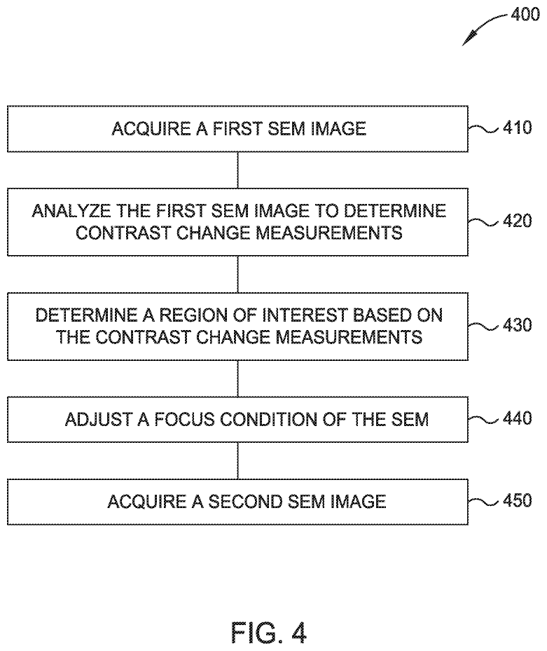

FIG. 4 illustrates a method 400 for determining a ROI containing one or more structural features of a FOV. In one embodiment, the ROI may be used to focus the SEM 110 of the imaging device 100. At operation 410, a first SEM image is acquired. For example, the processing system 130 may instruct SEM 110 to acquire the first SEM image. In one embodiment, the processing system 130 provides instructions to the electron gun 120 to scan the beam 112 onto sample 124 which causes the generation of the signal 114 which is received by the detector assembly 128. Further, the detector assembly 128 may generate the SEM image from the signal 114. In another embodiment, the detector assembly 128 outputs data corresponding to the signal 114 to the processing system 130 which generates the first image. In one embodiment, the processing system 130 configures the SEM with a first focus condition to acquire the first image. The first focus condition may place the sample 124 out of focus. In one embodiment, the processing system 130 determines the first focus condition by setting one or more of an objective lens current of the SEM, acceleration voltage of the SEM, working distance of the SEM, and a column voltage of the SEM.

At operation 420, the SEM image is analyzed to determine contrast change measurements between pixels of the SEM image. In one embodiment, the processing system 130 is configured to analyze the SEM image to determine contrast change measurements of the image. For example, the processing system 130 may compare each pixel of the SEM image to each neighboring pixel to determine a difference in contrast between each pixel. In one embodiment, the SEM image includes a plurality of rows and columns of pixels and the processing system 130 is configured to analyze the SEM image row by row and then column by column. For example, each pixel of a first row is compared to each neighboring pixel of the first row, and then each pixel of a second row is compared to each neighboring pixel of the second row. This process is repeated until each row of the SEM image has been analyzed. Additionally, each pixel of a first column is compared to each neighboring pixel of the first column, and then each pixel of a second column is compared to each neighboring pixel of the second column row. This process is repeated until each column of the SEM image has been analyzed. In one embodiment, the SEM image includes 512 rows and 512 columns. In other embodiments, the SEM image may include more or less rows and/or columns. Further, the number of rows and columns may not be the same.

A neighboring pixel may include any pixel that is adjacent to a pixel in a common row or column. Further, while rows and columns are described, in other embodiments, other configurations may be used.

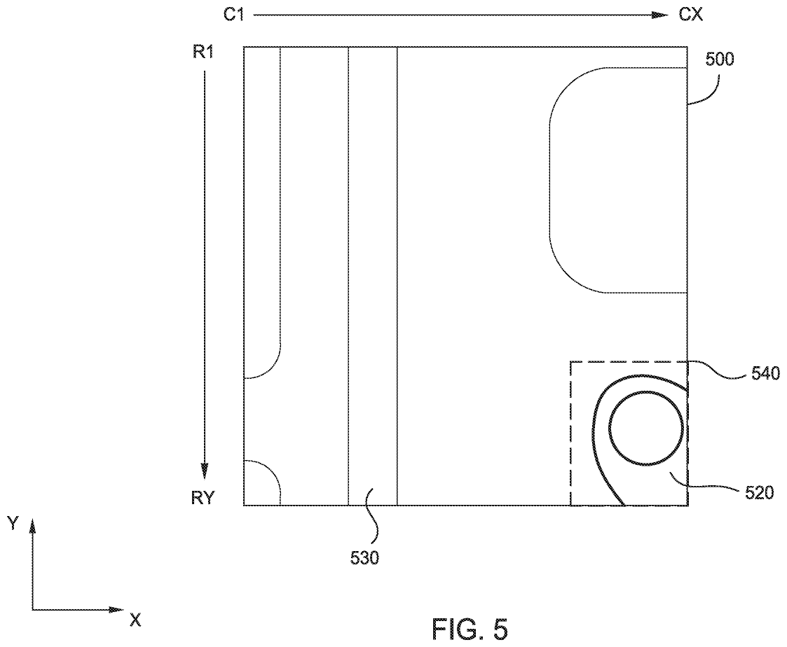

FIG. 5 illustrates a sample SEM image 500 that may be analyzed to determine a ROI. For example, the pixel of each row may be compared to each neighboring pixel of the row and the pixel of each column may be compared to each neighboring pixel of the column. As is illustrated in FIG. 5, the rows of pixels are along the Y direction, e.g., rows R1-RY and the columns of pixels are along the X direction, e.g., columns C1-CX. For example, a pixel of Row R1 is compared to each other pixel of R1 and each pixel of column C1 is compared to each other pixel of C1.

In one embodiment, to determine a difference in contrast for each pixel (e.g., the contrast change measurements), the brightness value of each pixel is compared to brightness value of each neighboring pixel. For example, the brightness value of each pixel may be subtracted from the brightness value of each neighboring pixel. A value corresponding to the difference in brightness between each pixel and each neighboring pixel may be referred to a contrast change measurement. Pixels having larger contrast change measurements may correspond to areas or locations of the image where structural features are located in in the image. Further, pixels having low contrast change measurements may correspond to areas of the image lacking structural features.

In one embodiment, a baseline value may be used to remove noise from the contrast change measurements. The baseline value may also be referred to as a contrast change baseline. The processing system 130 may be configured to compare each contrast change measurement of each pixel to a baseline value. In one embodiment, the processing system 130 finds a difference between the contrast change measurements and the baseline value. The contrast measurements that exceed the baseline value may be utilized to determine the ROI of interest. In other embodiments, the contrast change measurements that exceed the baseline values by a threshold amount may be utilized to determine the ROI of interest. In one embodiment, the threshold amount may be about 20 percent above the baseline values. In other embodiments, thresholds of less than or greater than 20 percent above the baseline values may utilized.

In one embodiment, the processing system 130 determines the baseline value by finding average contrast change of the SEM image. In other embodiments, the baseline value is based on a median or minimum value of the SEM image.

In one embodiment, if none of the contrast change measurements exceed the baseline value and/or satisfy the threshold value, it may be determined that SEM image may include too much noise and a new SEM image may be acquired. The SEM image may be taken for the same FOV or a new FOV.

At operation 430 a region of interest is determined based, at least in part, on the location of the contrast change measurements. For example, in one embodiment, the processing system 130 generates a contrast change map from the contrast change measurements. The contrast change map may be a two dimensional representation of the contrast change measurements. The processing system 130 may identify an area of the image corresponding to a location of maximum contrast change or changes. The location of maximum contrast change may be determined from the contrast change map or from any other representation of the contrast change measurements. Further, the processing system 130 may set the location of the ROI as the area having a maximum contrast change or variation.

For example, with reference to FIG. 5, the processing system 130 may generate a contrast change map from the contrast change measurements generated from the pixels of the SEM image 500. The processing system 130 may analyze the contrast change map and determine that the area 540 of the SEM image 500 may correspond to the maximum contrast change measurements. Thus, the processing system 130 may set the area 540 as being the ROI to be utilized for autofocus. In one embodiment, the ROI may be set to an area that is larger than area 540 but includes area 540.

In one embodiment, the size of the ROI may be about 10% to 20% of the area of the FOV used to acquire the SEM image. In other embodiments, the ROI may be less than 10% or greater than 20%. The area of the FOV may be about one or more square micrometers to about one or more square nanometers. In one embodiment, the size of the ROI and/or the FOV may vary depending on the amount of structural features present in the SEM image. For example, the selected ROI may have a smaller area than that of the ROI used in convention autofocus systems as the selected ROI is predetermined to include one or more structural features. Thus, a focusing routine performed on the selected ROI is faster as it is has a smaller area to analyze.

At operation 440, the focus condition of the SEM is adjusted. For example, the processing system 130 adjusts a focus condition of the SEM 110. In one embodiment, the processing system 130 acquires multiple images of the sample 124 using varied focus conditions and analyses the selected ROI of each SEM image to determine a sharpness gradient for each image. The ROI is the same for each SEM image. The SEM image corresponding to the high level of sharpness (e.g., having a peak contrast gradient) is selected to determine the optimum focus conditions of the SEM 110. For example, the processing system 130 may adjust the focus condition of the SEM 110 based on the identified image.

At operation 450 a second SEM image of the sample 124 is acquired. The second SEM image of the sample is acquired using the adjusted focus condition. In one embodiment, the processing system 130 is configured to perform CD measurements of the sample using the second SEM image. For example, the processing system 130 maybe be configured to measure the diameter of a connector 520 or the width of electrode 530. These measurements may be stored within a memory. Further, in one or more embodiments, the second SEM image may be utilized to examine one or more identified defects. The defects may be examined to determine if a defect was properly identified and/or to determine the cause of the defect.

While the foregoing is directed to embodiments of the present disclosure, other and further embodiments of the disclosure may be devised without departing from the basic scope thereof, and the scope thereof is determined by the claims that follow.

1. A method for focusing a scanning electron microscope (SEM), the method comprising:
acquiring a first SEM image of a sample using a first focus condition;
analyzing the first SEM image to determine contrast change measurements;
determining a region of interest based on the contrast change measurements;
acquiring two or more SEM images and determining a sharpness gradient for each of the two or more SEM images by analyzing the region of interest in each of the two more SEM images;
adjusting the SEM from the first focus condition to a second focus condition based at least in part on the sharpness gradient for each of the two or more SEM images, wherein the first focus condition differs from the second focus condition; and
acquiring a second SEM image of the sample using the second focus condition.

2. The method of claim 1, wherein the first SEM image comprises a plurality of pixels, and wherein analyzing the first SEM image comprises:
comparing each pixel of the plurality of pixels of the first SEM image to each neighboring pixel of the plurality of pixels; and
determining a contrast change measurement for each pixel of the plurality of pixels.

3. The method of claim 2, wherein determining the region of interest comprises:
determining a maximum contrast change measurement from the contrast change measurements and a location of the maximum contrast change measurement within the first SEM image; and
setting a position of the region of interest to correspond to the location of the maximum contrast change measurement.

4. The method of claim 2 further comprising:
generating a contrast change map from each of contrast change measurements.

5. The method of claim 2, wherein analyzing the first SEM image further comprises:
determining a contrast change baseline from the first SEM image; and
comparing each of the contrast change measurements with the contrast change baseline to generate baseline contrast change measurements.

6. The method of claim 5, wherein determining the contrast change baseline comprises determining an average contrast change measurement from the contrast change measurement.

7. The method of claim 1, wherein an area of the region of interest is smaller than an area of the first SEM image.

8. A computer program product for focusing a scanning electron microscope (SEM), the computer program product comprising:
a non-transitory computer-readable storage medium having computer-readable program code embodied therewith, the computer-readable program code executable by one or more computer processors to:
acquire a first SEM image of a sample using a first focus condition;
analyze first SEM image to determine contrast change measurements;
determine a region of interest based on the contrast change measurements;
acquire two or more SEM images and determine a sharpness gradient for each of the two or more SEM images by analyzing the region of interest in each of the two more SEM images;
adjust the SEM from the first focus condition to a second focus condition based at least in part on the sharpness gradient for each of the two or more SEM images, wherein the first focus condition differs from the second focus condition; and
acquire a second image of the sample using the second focus condition.

9. The computer program product of claim 8, wherein the first SEM image comprises a plurality of pixels, and wherein analyzing the first SEM image comprises:
comparing each pixel of the plurality of pixels of the first SEM image to each neighboring pixel of the plurality of pixels; and
determining a contrast change measurement for each pixel of the plurality of pixels.

10. The computer program product of claim 9, wherein determining the region of interest comprises:
determining a maximum contrast change measurement from the contrast change measurements and a location of the maximum contrast change measurement within the first SEM image; and
setting a position of the region of interest to correspond to the location of the maximum contrast change measurement.

11. The computer program product of claim 10 further comprising:
generating a contrast change map from each of contrast change measurements.

12. The computer program product of claim 9, wherein analyzing the first SEM image further comprises:
determining a contrast change baseline from the first SEM image; and
comparing each of the contrast change measurements with the contrast change baseline to generate baseline contrast change measurements.

13. The computer program product of claim 12, wherein determining the contrast change baseline comprises determining an average contrast change measurement from the contrast change measurement.

14. The computer program product of claim 8, wherein an area of the region of interest is smaller than an area of the first SEM image.

15. A testing device, comprising:
a scanning electron microscope (SEM); and
a processing system coupled to the SEM, the processing system configured to:
acquire a first SEM image of a sample using a first focus condition;
analyze the first SEM image to determine contrast change measurements;
determine a region of interest based on the contrast change measurements;
acquire two or more SEM images and determine a sharpness gradient for each of the two or more SEM images by analyzing the region of interest in each of the two more SEM images;
adjust the SEM from the first focus condition to a second focus condition based at least in part on the sharpness gradient for each of the two or more SEM images, wherein the first focus condition differs from the second focus condition; and
acquire a second image of the sample using the second focus condition.

16. The testing device of claim 15, wherein the first SEM image comprises a plurality of pixels, and wherein analyzing the first SEM image comprises:
comparing each pixel of the plurality of pixels of the first SEM image to each neighboring pixel of the plurality of pixels; and
determining a contrast change measurement for each pixel of the plurality of pixels.

17. The testing device of claim 16, wherein determining the region of interest comprises:
determining a maximum contrast change measurement from the contrast change measurements and a location of the maximum contrast change measurement within the first SEM image; and
setting a position of the region of interest to correspond to the location of the maximum contrast change measurement.

18. The testing device of claim 16, wherein analyzing the first SEM image further comprises:
determining a contrast change baseline from the first SEM image; and
comparing each of the contrast change measurements with the contrast change baseline to generate baseline contrast change measurements.

19. The testing device of claim 18, wherein determining the contrast change baseline comprises determining an average contrast change measurement from the contrast change measurement.

20. The testing device of claim 15, wherein an area of the region of interest is smaller than an area of the first SEM image.
